(19) United States
(12) Patent Application Publication
(10) Pub. No.: US 2020/0139490 A1
(43) Pub. Date: May 7, 2020

(54) Solder Preform for Diffusion Soldering, Method for the Production thereof, and Method for the Assembly Thereof

(71) Applicant: Siemens Aktiengesellschaft, München (DE)

(72) Inventors: Jörg Strogies, Berlin (DE); Klaus Wilke, Berlin (DE); Christian Schellenberg, Potsdam (DE)

(73) Assignee: Siemens Aktiengesellschaft, München (DE)

(21) Appl. No.: 16/607,543

(22) PCT Filed: Apr. 19, 2018
(86) PCT No.: PCT/EP2018/059971

§ 371 Date: Oct. 23, 2019

(30) Foreign Application Priority Data
Apr. 25, 2017 (DE) 10 2017 206 930.9

(51) Int. Cl. B23K 35/02; B32B 15/16; H01L 23/00

(52) U.S. Cl. CPC B23K 35/025; B32B 15/16; H01L 24/29; H01L 2224/8382; H01L 2224/2908; H01L 2224/29006; H01L 24/83

(57) ABSTRACT

Various embodiments include a solder preform for diffusion soldering comprising a sandwich structure having a multiplicity of first layers and a multiplicity of second layers alternating with one another in the sandwich structure. The first layers each comprise a metal foil. The second layers each comprise metal particles and a binder forming a paste.

### CROSS-REFERENCE TO RELATED APPLICATIONS

This application is a U.S. National Stage Application of International Application No. PCT/EP2018/059971 filed Apr. 19, 2018, which designates the United States of America, and claims priority to DE Application No. 10 2017 206 930.9 filed Apr. 25, 2017, the contents of which are hereby incorporated by reference in their entirety.

### TECHNICAL FIELD

The present disclosure relates to soldering. Various embodiments may include a solder preform for diffusion soldering, having a sandwich structure (abbreviated below to sandwich) consisting of first layers of a first material and of second layers of a second material, the first layers and the second layers alternating with one another in the sandwich.

### BACKGROUND

The use of diffusion soldering connections for assembling two connection partners is described, for example, in DE 10 2013 219 642 A1. During the formation of diffusion soldering connections between the connection partners, as a result of diffusion processes, a soldering connection is formed which comprises an intermetallic phase that has a higher melting point than the rest of the soldering connection consisting of the solder alloy. In this way, it is possible to thermally and mechanically stabilize the connection between the connection partners.

The connection partners may, for example, provide contact materials made of copper. The diffusion solder may be a solder material containing tin. Due to the diffusion of copper into the solder material during the formation of the soldering connection, a diffusion zone is then created, which is formed by intermetallic bonding between copper and tin. This has a melting point of about 420°, which is therefore clearly above the melting temperature of the tin-based solder material. Because of the diffusion processes required, the diffusion zone cannot extend to an arbitrary depth in the solder material. The soldering connection to be formed is therefore restricted to a particular thickness. It is proposed in DE 10 2013 219 642 A1 to configure at least one of the connection partners in such a way that cavities are created in the region of the connection gap between the connection partners. These may, for example, be formed by providing indentations in the assembly surface of one of the connection partners. They then serve during the connecting as buffer spaces, into which excess solder material can escape so that, even when quantity tolerances arise, it is possible to ensure a gap width between the connection partners that ensures reliable formation of a diffusion zone over the entire width of the connection gap.

D. Feil: “Fügekonzepte für Leistungsmodule an Kühlkörper” [Concepts for connecting power modules to heat sinks], Elektronische Baugruppen and Leiterplatten [Electronic modules and circuit boards], pages 60-64, Berlin, Offenbach, 2016, states even relatively large connection gaps between the connection partners may be bridged during the formation of diffusion soldering connections if a flexible preform, for example a copper mesh, is placed in the connection gap. A solder foil may be placed thereon, the solder material filling the intermediate spaces between the flexible preform when it liquefies. The preform in this case provides the material which can diffuse into the solder material. Because the diffusing material is provided not only by the interfaces of the connection partners but also inside the soldering connection, a continuous diffusion zone may be formed between the connection partners even in the case of a relatively large connection gap.

Feil also describes another possibility for the formation of diffusion soldering connections, in which a metal powder, for example copper powder, is used instead of the flexible preform. This powder is admixed with the solder material and provides, dispersedly distributed in the solder material, the material which can diffuse into the soldering connection so as to form the diffusion zone. In this way as well, a diffusion zone that bridges the gap between the connection partners is produced in the soldering connection.

According to US 2009/004500 A1, diffusion soldering connections between two connection partners may be produced by diffusion of constituents from a liquid phase into a solid phase during the soldering. In this case, a solder material containing two components is used between the connection partners. In order to be able to produce the soldering connection, a solder preform, which consists of a sandwich of layers of the first component and of the second component, is placed between the connection partners. In this way, it is possible to keep the diffusion paths for the diffusing element as short as possible, so that a mechanically stable connection between the connection partners is obtained.

The use of solder preforms requires high precision in the production of the soldering connections, since they must touch both connection partners in order to form reliable contact and the diffusion paths in the soldering connection being formed must not be too long. This precision entails a certain manufacturing outlay (for example a high degree of parallelism of the surfaces to be connected) and associated costs.

### SUMMARY

The teachings of the present disclosure include solder preforms for diffusion soldering, methods for the production thereof, and methods for the assembly thereof between two connection partners, with it being possible to produce soldering connections economically and with improved processability with the solder preform. For example, some embodiments include a solder preform for diffusion soldering, having a sandwich structure consisting of first layers (12) of a first material and of second layers (13) of a second material, the first layers (12) and the second layers (13) alternating with one another in the sandwich structure, characterized in that the first material is configured as a metal foil (14), of which the first layers (12) consist, and the second material consists of metal particles (15) which, with a binder (16), form a paste, the second layers consisting of the paste.

In some embodiments, the first material is a solder material and the second material has a higher melting point than the first material.

In some embodiments, the second material is a solder material and the first material has a higher melting point than the second material.

As another example, some embodiments include a method for producing a solder preform (11), in which first layers (12) of a first material and second layers (13) of a second material are stacked to form a sandwich structure, the first layers (12) and the second layers (13) alternating with one another in the sandwich structure, characterized in that the first material is configured as a metal foil (14), of which the first layers (12) consist, and the second material consists of metal particles (15), which are processed with a binder (16) to form a paste, the second layers (13) being produced from the paste.

In some embodiments, the foil (14) is coated with the paste, before the foil (14) coated in this way is stacked to form the sandwich structure.

In some embodiments, a plurality of solder preforms (11) are produced simultaneously by producing the sandwich structure with a greater area than the solder preforms (11) and separating the solder preforms (11) therefrom.

In some embodiments, a solder preform (11) is placed between a first connection partner (24) and a second connection partner (25) and the solder preform (11) is melted to form the diffusion soldering connection (23), characterized in that a solder preform (11) as described above is used.

In some embodiments, a solder preform (11) having an oversize taking into account the shrinkage (Δz) of the solder material is used.

In some embodiments, a solder preform (11) having an oversize (t) taking into account the tolerances of the diffusion soldering connection is used.

### BRIEF DESCRIPTION OF THE DRAWINGS

Further details of the teachings herein are described below with the aid of the drawings. Drawing elements which are the same or correspond to one another are respectively provided with the same references and will be explained repeatedly only when differences arise between the individual figures.

FIGS. 1 and 2 show exemplary embodiments of an example solder preform incorporating the teachings herein schematically as a cross section;

FIGS. 3 to 5 show selected method steps of an example embodiment of a method incorporating teachings of the present disclosure for producing a solder preform, in section; and

FIGS. 6 and 7 show selected method steps of example embodiments of methods incorporating teachings of the present disclosure for making a diffusion soldering connection, in section or as a side view.

### DETAILED DESCRIPTION

With the preforms described above, the first material is configured as a metal foil, of which the first layers consist. The second material consists of metal particles which, with a binder, form a paste, the second layers consisting of the paste. From the first material and the second material, a diffusion zone, which preferably consists of intermetallic compounds, may thus be produced in the soldering connection formed during the soldering. In some embodiments, the paste may in this case be used for tolerance compensation since it is deformable before the soldering and the solder preform may therefore be impressed as a whole in the assembly direction. In this case, the paste is partially displaced out of the intermediate space lying between two neighboring foils. Furthermore, the paste experiences a certain volume shrinkage during the soldering process since the binder escapes from the soldering connection during the soldering process. The volume shrinkage, however, assists the bridging of manufacturing and assembly tolerances since it can be variable within certain limits.

In some embodiments, the first material is a solder material and the second material has a higher melting point than the first material. The first material may for example be a tin-based solder material (in particular a tin-silver-copper solder, for example SAC305 with the alloy composition SN96.5Ag3Cu0.5 or a tin-copper solder, for example with the alloy composition Sn99.3Cu0.7), while the second material is a metal that dissolves in the tin material and can diffuse therein, preferably copper. The copper material is then fixed between the foils of the first material with the aid of the binder, for example by a screen printing method, the diffusion paths of the particle material being determined by the thickness of the foil of solder material.

In some embodiments, the second material is a solder material and the first material has a higher melting point than the second material. In this case, the foils of the first material may be made very thin, the second material being applied onto the foils in the form of a solder material. In particular, a screen printing method may be used.

In some embodiments of a method for producing a solder preform, the first material is configured as a metal foil, from which the first layers are produced, and the second material consists of metal particles, which are processed with a binder to form a paste, the second layers being produced from the paste. The advantages when carrying out this method have already been mentioned. In some embodiments, the second material, which consists of the paste, may be applied easily onto the first material in the form of the metal foil, it being for example possible to use a screen printing method. The foil coated in this way may then advantageously be stacked on the sandwich structure. The number of stacked foils determines the thickness of the sandwich structure, and the latter may be determined while taking into account the gap dimension of the soldering connection to be formed. In this case, as already described, the degree of shrinkage when forming the soldering connection, by which the height of the sandwich structure needs to be increased in relation to the gap dimension to be bridged, is to be taken into account.

In some embodiments, a plurality of solder preforms are produced simultaneously by producing the sandwich structure with a greater area than the solder preforms and separating the solder preforms therefrom. In other words, a large-area semifinished product is produced, which may in particular be produced particularly simply by a screen printing method. This is then divided to form the solder preforms. This may, for example, be done by stamping or laser cutting. The solder preforms may be produced in a large number and, for example, provided on tapes for electronics assembly for fitting on circuit carriers.

In some embodiments, a solder preform of the type described above is used. In some embodiments, a solder preform having an oversize taking into account the shrinkage of the solder material is used.

Furthermore, an oversize taking into account the tolerances of the diffusion soldering connection may be provided, which in particular is added to the oversize taking into account the shrinkage of the solder material. In this way, diffusion soldering connections affected by tolerances may be produced with high reliability, to which end it is possible to use solder preforms that are economical to produce and may be made available in a large number in the assembly process. In particular, the diffusion soldering connections may be made with tolerance requirements generally applicable for electronics assembly, so that the production of the diffusion soldering connections may be integrated into the normal process of electronics assembly. In this way, particularly economical technical solutions are advantageously achieved.

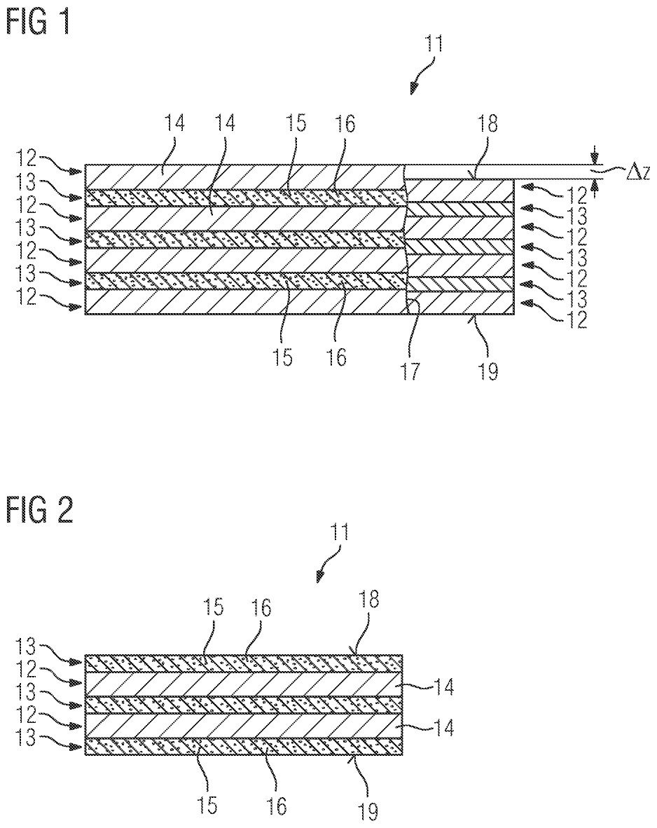

A solder preform 11 as shown in FIG. 1 comprises first layers 12 and second layers 13, arranged in alternation (represented on the left-hand side of a break line 17). The first layers 12 consist of a metal foil 14, which according to FIG. 1 is produced from a solder material, for example a tin-silver-copper alloy (or another tin-based alloy). The second layers 13 consist of a paste, particles 15 being distributed in a binder 16. The particles 15 comprise copper. In some embodiments, they may also comprise nickel.

In FIG. 1, on the right-hand side of the break line 17, a diffusion soldering connection is also represented after a process of soldering the solder preform 11 has been carried out. The connection partners, which follow on from an upper connection surface 18 and a lower connection surface 19, are not represented in FIG. 1. It can, however, be seen that the second layers 13 are now formed by metallic copper and, in comparison with the second layers 13 to the left of the break line 17, have a smaller thickness since the binder 16 is no longer present. Overall, this gives rise to a shrinkage Δz that determines the height of the diffusion soldering connection to be formed. This shrinkage Δz must be taken into account when determining the required thickness of the solder preform 11.

The reduction of the thickness of the second layers 13 has, however, another reason. This is because a part of the copper is diffused into the first layers 12 so that diffusion zones are created here. These consist at least partially of intermetallic phases, which on the one hand contain the material of the solder material and on the other hand the material of the particles, and stabilize the soldering connection mechanically and thermally. In FIG. 1, the first layers 12 consist entirely of the intermetallic compound.

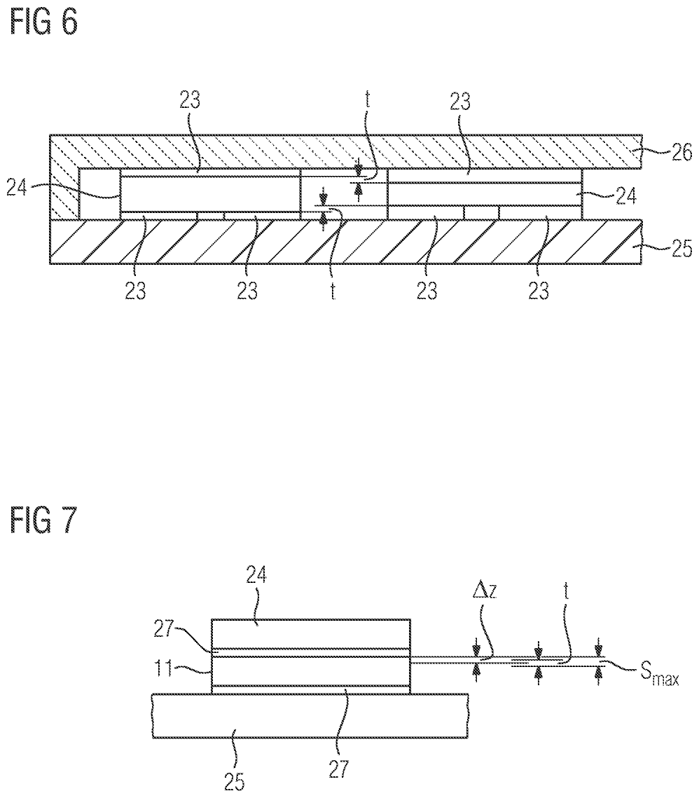

As shown in FIG. 2, a further exemplary embodiment of the sandwich structure of the solder preform 11 is represented. The first layers 12 are in this case formed from the foil 14 of copper, while the second layers 13 are formed from the paste consisting of particles 15 of a tin-containing solder material and the binder 16. For FIG. 1 and FIG. 2, it is the case that the top layer and the bottom layer, which respectively form the upper connection surface 18 and the lower connection surface 19, consist of the solder material so that connection to the adjacent connection partners is possible (cf. FIG. 6).

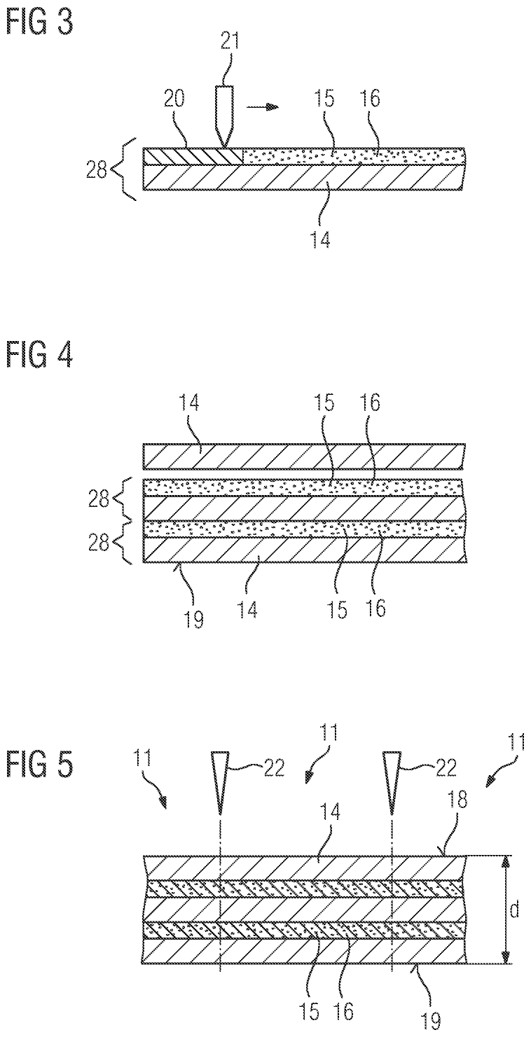

In FIGS. 3 to 5, selected method steps for the production of the solder preform 11 according to FIG. 1 are represented. The solder preform according to FIG. 2 may, however, be produced likewise.

In FIG. 3, for simpler production of the solder preform 11 (cf. also FIG. 5), the foil 14 is coated with a mask 20 and a blade 21 in screen printing technology with the paste, consisting of the particles 15 and the binder 16. In this way, a semifinished product 28 is formed, which in the next step according to FIG. 4 may be coated until the required thickness d for the semifinished product 28 is reached (cf. FIG. 5). In order to ensure the structure of first layers 12 and second layers 13 according to FIG. 1, another foil 14 without paste must subsequently be placed on the top semifinished product 28.

From the sandwich structure according to FIG. 4, according to FIG. 5 a multiplicity of semifinished solder products 11 may be produced, for example by individualizing these using a saw, a stamping tool or a knife 22. The knife 22 (or the stamping tool or the saw) cuts the sandwich structure according to FIG. 4 along the dot-and-dash lines indicated into semifinished solder products 11 with the desired size.

In FIG. 6, the way in which diffusion soldering connections 23 that connect a first connection partner 24 to a second connection partner 25, as well as to a third connection partner 26, may be produced from the solder preforms is represented. The first connection partner 24 according to FIG. 6 consists of power semiconductor components, which are fastened on the second connection partner 25, a circuit board, by means of the diffusion soldering connections 23. Furthermore, the first connection partners 24 likewise have diffusion soldering connections 23 on the opposite upper side, which are electrically connected to the third connection partner 26, a ceramic component in the form of a cap. In FIG. 6, it is furthermore clear that the height of the first connection partners may vary because of tolerances t. For this reason, a diffusion soldering connections 23 according to FIG. 6 have different thicknesses, and tolerance compensation may respectively be carried out by the second layers (not represented in FIG. 6) which may be compressed more greatly or less greatly as a function of tolerances during the assembling of the connection partners.

In a higher degree of detail, the way in which the first connection partner 24 in the form of a component may be connected to the second connection partner 25 in the form of a circuit board by means of the diffusion soldering connection is represented in FIG. 7. Both the first connection partner 24 and the second connection partner 25 comprise mentalizations 27 made of copper, adjacent to which the solder preform 11 is placed. During soldering, material of the mentalizations 27 diffuses into the diffusion soldering connection being formed, and participates (not represented) there in the formation of the intermetallic phases in a diffusion zone.

During the soldering process, the solder preform 11 melts, during which the shrinkage Δz takes place. The first connection partner 24 is in this case lowered by the amount Δz. However, the second layers (not represented in detail in FIG. 7) allow maximum lowering by sₘₐₓ, so that a tolerance range t due to manufacturing and assembly tolerances may additionally be compensated for during the production of the diffusion soldering connection. In this case, it is to be taken into account that lowering of the first connection partner 24 by a value less than Δz is also possible because of the tolerances t, although in this case a diffusion soldering connection with sufficient quality is still created.

What is claimed is:

1. A solder preform for diffusion soldering, the preform comprising:
a sandwich structure having a multiplicity of first layers and a multiplicity of second layers alternating with one another in the sandwich structure;
wherein the first layers each comprise a metal foil; and
the second layers each comprise metal particles and a binder forming a paste.

2. The solder preform as claimed in claim 1, wherein:
the metal foil comprises a solder material; and
the paste has a higher melting point than a melting point of the solder material.

3. The solder preform as claimed in claim 1, wherein:
the paste comprises a solder material; and
the metal foil has a higher melting point than a melting point of the paste.

4. A method for producing a solder preform, the method comprising:
stacking a multiplicity of first layers with a multiplicity of second layers to form a sandwich structure;
wherein the first layers and the second layers alternate with one another in the sandwich structure;
wherein each of the first layers comprises a metal foil; and
each of the second layers comprises metal particles and a binder form a paste.

5. The method as claimed in claim 4, further comprising coating each layer of metal foil the paste;
Then stacking each layer of coated metal foil to form the sandwich structure.

6. The method as claimed in claim 4, further comprising forming a plurality of solder preforms simultaneously by producing the sandwich structure with a greater area than the solder preforms and separating the solder preforms therefrom.

7. A method for making a diffusion soldering connection, the method comprising:
placing a solder preform between a first connection partner and a second connection partner; and
melting the solder preform to form the diffusion soldering connection;
wherein the solder preform comprises:
a sandwich structure having a multiplicity of first layers and a multiplicity of second layers alternating with one another in the sandwich structure;
wherein the first layers each comprise a metal foil; and
the second layers each comprise metal particles and a binder forming a paste.

8. The method as claimed in claim 7, wherein a solder preform having an oversize based on a predicted shrinkage of the solder material is used.

9. The method as claimed in claim 7, wherein a solder preform having an oversize based on tolerances of the diffusion soldering connection is used.
